(19) United States
(12) Patent Application Publication
(10) Pub. No.: US 2015/0235071 A1
(43) Pub. Date: Aug. 20, 2015

(54) Biometrics Sensor Having Flat Contact Surface Formed by Signal Extending Structure and Method of Manufacturing Such Sensor

(71) Applicant: J-METRICS TECHNOLOGY CO., LTD., Taipei City (TW)

(72) Inventor: Jer-Wei CHANG, Hsinchu City (TW)

(21) Appl. No.: 14/622,384

(22) Filed: Feb. 13, 2015

(30) Foreign Application Priority Data
Feb. 17, 2014 (TW) 103105038

(51) Int. Cl. G06K 9/00; H01L 21/768; H01L 25/00; H01L 21/56

(52) U.S. Cl. CPC G06K 9/00033; H01L 21/56; H01L 21/76838; H01L 25/50

(57) ABSTRACT

A biometrics sensor comprises: a base; a biometrics sensing module disposed on the base and comprising a biometrics sensing chip and a signal extending structure, both of which functionally link with each other to sense a fine biometrics characteristic of an organism to obtain a biometrics signal; a signal transmission structure disposed on the base and one side or sides of the biometrics sensing module and having a first connection end electrically connected to the signal extending structure, and a second connection end near the base, so that the biometrics signal is transmitted from the biometrics sensing module to the second connection end; and a molding layer, connected to the base, the biometrics sensing module and the signal transmission structure, with an upper surface of the signal extending structure being exposed from the molding layer. A method of manufacturing the biometrics sensor is also disclosed.

This application claims priority of No. 103105038 filed in Taiwan R.O.C. on Feb. 17, 2014 under 35 USC 119, the entire content of which is hereby incorporated by reference.

### BACKGROUND OF THE INVENTION

1. Field of the Invention

The invention relates to a biometrics sensor and a method of manufacturing such sensor, and more particularly to a biometrics sensor having a flat contact surface formed by a signal extending structure, and a method of manufacturing such sensor.

2. Related Art

The conventional capacitive/electric field sensing technique applied to the sensing of the human body skin may be applied to a fingerprint sensor for sensing the finger's texture or a touch panel or display for capacitive/electric field touching. More particularly, a sensor, such as a sensor for sensing a finger skin texture, has array-type sensing members serving as the basic structure to be in contact with the skin texture. That is, several sensing members, which are the same, constitute a two-dimensional sensor. When a finger, for example, is placed on the sensor, the ridge of the finger texture directly contacts the sensor, and a gap is present between the valley of the finger texture and the sensor. According to these properties that the sensing member directly contacts the ridge or the other sensing member is separated from the valley by a gap, the finger texture can be captured from the two-dimensional capacitive/electric field image. This is the basic principle of the capacitive/electric field skin texture sensor.

FIG. 1A is a schematic view showing a conventional fingerprint sensor device. Referring to FIG. 1A, the fingerprint sensor device 500 comprises a package substrate 510, a fingerprint sensor 520, a plurality of wires 530 and a package layer 540. The fingerprint sensor 520 is disposed on the package substrate 510. The wires 530 electrically connect bonding pads 522 of the fingerprint sensor 520 to bonding pads 512 of the package substrate 510. In addition, a chip protection layer 514 covers the fingerprint sensor 520.

The maximum characteristic of such the capacitive/electric field fingerprint sensor device in use is to let the sensing surface be in contact with the skin texture so that the texture image can be sensitively constructed. One restriction of the conventional fingerprint sensor device in the package process is to have the exposed surface to be in contact with the finger to sense the image of the finger texture. Thus, in the package process, a special mold and a flexible material layer have to be used to protect the sensing surface of the fingerprint sensing chip, and two sides or the circumference of the packaged product is provided with the package layer 540 for protecting wires, and is thus higher than the middle sensing surface portion, as shown by the two sides of FIG. 1A. Thus, the finger tends to be blocked by the circumferential package layer when the sensor is being used, so that the finger cannot be easily in direct contact with the sensing surface, thereby affecting the image quality of the fingerprint sensor device.

Meanwhile, when the sweep-type fingerprint sensor device 500 in FIG. 1A, for example, is embedded into an electronic apparatus (e.g., mobile phone) 600, as shown in FIG. 1B, the housing 610 of the electronic apparatus 600 must have an opening 611, and top and bottom sides of the opening 611 must be formed with the concave slideway 612 for guiding the finger to contact the chip protection layer 514 of the fingerprint sensor device 500 and enter the sensing region. Consequently, the overall beauty of the electronic apparatus 600 is seriously damaged, and the dust tends to be left in the clearance 613 between the fingerprint sensor device 500 and the opening 611, thereby affecting the beauty and cleanness.

### SUMMARY OF THE INVENTION

It is therefore an object of the invention to provide a biometrics sensor having a flat contact surface formed by a signal extending structure, and a method of manufacturing such biometrics sensor. The signal extending structure can be formed by the semiconductor manufacturing process, and the electric contact points are guided to the back side of the biometrics sensor. This is advantageous to the manufacturing of the substantially all-flat or completely all-flat biometrics sensor. Meanwhile, the signal extending structure may also be used to enhance the sensitivity and image quality.

To achieve the above-identified object, the invention provides a biometrics sensor, comprising: a base; a biometrics sensing module, which is disposed on an upper surface of the base, and comprises a biometrics sensing chip and a signal extending structure, wherein the signal extending structure is disposed on and electrically connected to the biometrics sensing chip, the signal extending structure and the biometrics sensing chip functionally link with each other to sense a fine biometrics characteristic of an organism, contacting or approaching the biometrics sensor, to obtain a biometrics signal; a signal transmission structure, which is disposed on the base and one side or sides of the biometrics sensing module, and has a first connection end electrically connected to the signal extending structure, and a second connection end near the base, so that the biometrics signal is transmitted from the biometrics sensing module to the second connection end, wherein the signal extending structure comprises a horizontally outwardly expanded connection structure electrically connecting connection pads of the biometrics sensing chip to the signal transmission structure; and a molding layer, connected to the base, the biometrics sensing module and the signal transmission structure, so that a sensing surface and an electrical signal interface of the biometrics sensor are disposed on a front side and a back side of the biometrics sensor, respectively.

The invention also provides a method of manufacturing a biometrics sensor, the method comprising the steps of: (a) providing a biometrics sensing chip; (b) forming one portion of a signal extending structure on the biometrics sensing chip to constitute one portion of a biometrics sensing module; (c) providing a base structure having a base and a signal transmission structure disposed on the base; (d) disposing the one portion of the biometrics sensing module on an upper surface of the base with the signal transmission structure being disposed on one side or sides of the biometrics sensing module; (e) utilizing a molding layer connected to the base, the one portion of the biometrics sensing module and the signal transmission structure with the one portion of the signal extending structure being exposed from the molding layer; and (f) forming the other portion of the signal extending structure to electrically connect the one portion of the signal extending structure to the signal transmission structure, wherein the signal extending structure comprises a horizontally outwardly expanded connection structure, which electrically connects connection pads of the biometrics sensing chip to the signal transmission structure, the signal extending structure and the biometrics sensing chip functionally link with each other to sense a fine biometrics characteristic of an organism, contacting or approaching the signal extending structure, to obtain a biometrics signal transmitted to the signal transmission structure, so that a sensing surface and an electrical signal interface of the biometrics sensor are disposed on a front side and a back side of the biometrics sensor, respectively.

The invention further provides a biometrics sensor, comprising: a base; a biometrics sensing module, which is disposed on an upper surface of the base and comprises a biometrics sensing chip, a signal processing chip and a signal extending structure, wherein the signal extending structure is disposed on and electrically connected to the biometrics sensing chip and the signal processing chip, the signal extending structure functionally links with the biometrics sensing chip and the signal processing chip to sense a fine biometrics characteristic of an organism, contacting or approaching the biometrics sensor, to obtain a biometrics signal, and the signal processing chip receives and processes a sensing signal coming from the biometrics sensing chip to obtain the biometrics signal; a signal transmission structure, which is disposed on the base and one side or sides of the biometrics sensing module, and has a first connection end electrically connected to the signal extending structure, a second connection end near the base and a middle connection portion electrically connected to the biometrics sensing chip and the signal processing chip, wherein the signal transmission structure transmits the biometrics signal from the biometrics sensing module to the second connection end, wherein the signal extending structure comprises a horizontally outwardly expanded connection structure electrically connecting output connection pads of the signal processing chip to the signal transmission structure; and a molding layer connected to the base, the biometrics sensing module and the signal transmission structure with a sensing surface and an electrical signal interface of the biometrics sensor being disposed on a front side and a back side of the biometrics sensor, respectively.

The invention further provides a method of manufacturing a biometrics sensor, the method comprising the steps of: (a) providing a biometrics sensing chip and a signal processing chip; (b) forming one portion of a signal extending structure on the biometrics sensing chip and the signal processing chip to constitute one portion of a biometrics sensing module; (c) providing a base structure having a base and a signal transmission structure disposed on the base; (d) disposing the one portion of the biometrics sensing module on an upper surface of the base with the signal transmission structure being disposed on one side or sides of the biometrics sensing module; (e) utilizing a molding layer connected to the base, the one portion of the biometrics sensing module and the signal transmission structure with the one portion of the signal extending structure being exposed from the molding layer; and (f) forming the other portion of the signal extending structure to electrically connect the one portion of the signal extending structure to the signal transmission structure, and to electrically connect the biometrics sensing chip to the signal processing chip, wherein the signal extending structure functionally links with the biometrics sensing chip and the signal processing chip to sense a fine biometrics characteristic of an organism, contacting or approaching the signal extending structure, to obtain a biometrics signal transmitted to the signal transmission structure, so that a sensing surface and an electrical signal interface of the biometrics sensor are disposed on a front side and a back side of the biometrics sensor, respectively, wherein the signal processing chip receives and processes a sensing signal coming from the biometrics sensing chip to obtain the biometrics signal.

With each fingerprint sensor of the invention, the signal extending structure is used to guide the electrical signal from the front side of the fingerprint sensing chip to the outside of the fingerprint sensing chip, and then the signal transmission structure is utilized to guide the electrical signal to the back side of the sensing chip so that an all-flat fingerprint sensor can be implemented. Because the fingerprint sensor according to each embodiment of the invention can be manufactured using the semiconductor manufacturing process and/or the semiconductor package process, the mass production and the cost down objects can be achieved. Furthermore, disposing the biometrics sensing chip and the signal processing chip separately may also effectively decrease the cost.

Further scope of the applicability of the present invention will become apparent from the detailed description given hereinafter. However, it should be understood that the detailed description and specific examples, while indicating preferred embodiments of the present invention, are given by way of illustration only, since various changes and modifications within the spirit and scope of the present invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus are not limitative of the present invention.

FIG. 1A is a schematic view showing a conventional fingerprint sensor device.

FIG. 1B is a schematic view showing an electronic apparatus using the fingerprint sensor device of FIG. 1A.

FIG. 2A is a schematic view showing a biometrics sensor according to a first embodiment of the invention.

FIG. 2B is a schematic view showing a biometrics sensor according to a second embodiment of the invention.

FIG. 2C is a schematic view showing a biometrics sensor according to a third embodiment of the invention.

FIG. 2D is a schematic view showing a biometrics sensor according to a fourth embodiment of the invention.

FIGS. 3A to 3I are FIGS. 4A to 4O are schematic views showing structures in steps of the method of manufacturing the biometrics sensor according to the first embodiment of the invention.

FIGS. 5A and 5B are schematic views showing structures in steps of the method of manufacturing the biometrics sensor according to the second embodiment of the invention.

FIGS. 6A to 6C are schematic views showing three examples of electronic apparatuses using the biometrics sensor of the invention.

FIG. 7A is a schematic view showing a biometrics sensor according to a fifth embodiment of the invention.

FIG. 7B is a partial pictorial view showing the biometrics sensor according to the fifth embodiment of the invention.

### DETAILED DESCRIPTION OF THE INVENTION

The present invention will be apparent from the following detailed description, which proceeds with reference to the accompanying drawings, wherein the same references relate to the same elements.

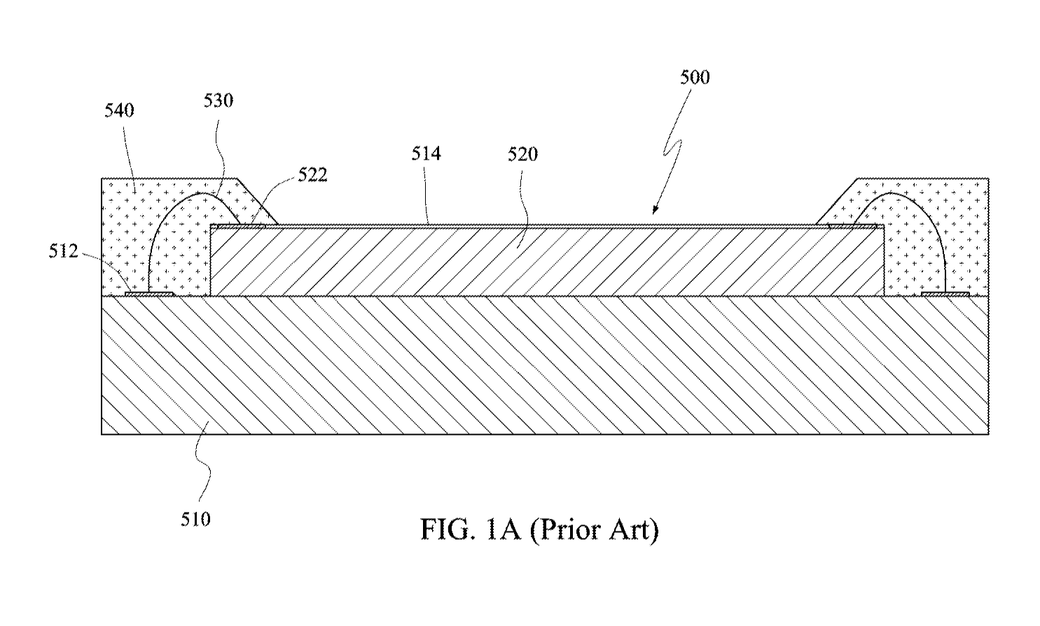

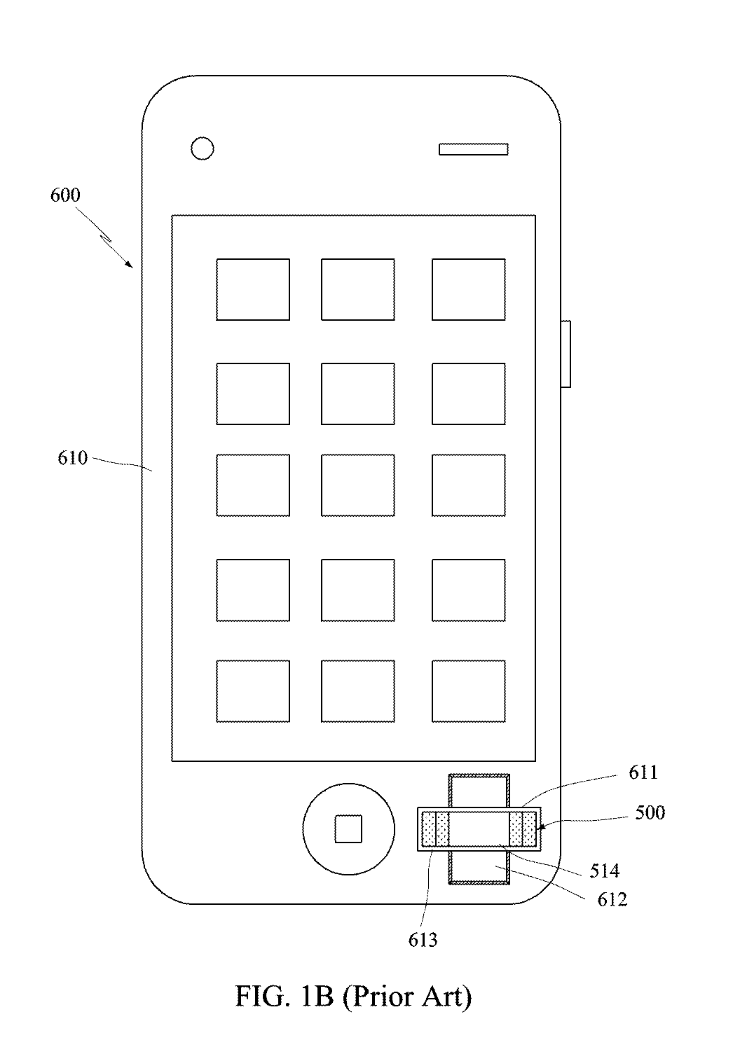

The fingerprint sensor according to an embodiment of the invention is to utilize a signal extending structure to guide an electrical signal from a front side of a fingerprint sensing chip (the one side to be in contact with a finger) to the outside of the fingerprint sensing chip, and further utilize a signal transmission structure to guide the electrical signal to the back side of the fingerprint sensing chip, so that the sensing surface and the electrical signal interface are disposed on the front and back sides of the sensing chip, respectively. Such a design is free of the condition that the peripheral wire-bond package layer 540 interferes with the contact of the finger in the example of FIG. 1A. The sensor of the embodiment of the invention is referred to as an all flat fingerprint sensor. Because the fingerprint sensor according to the embodiment of the invention can be manufactured by the semiconductor wafer-level process, which replaces the conventional die package process, the mass automatic production and the cost reduction can be achieved.

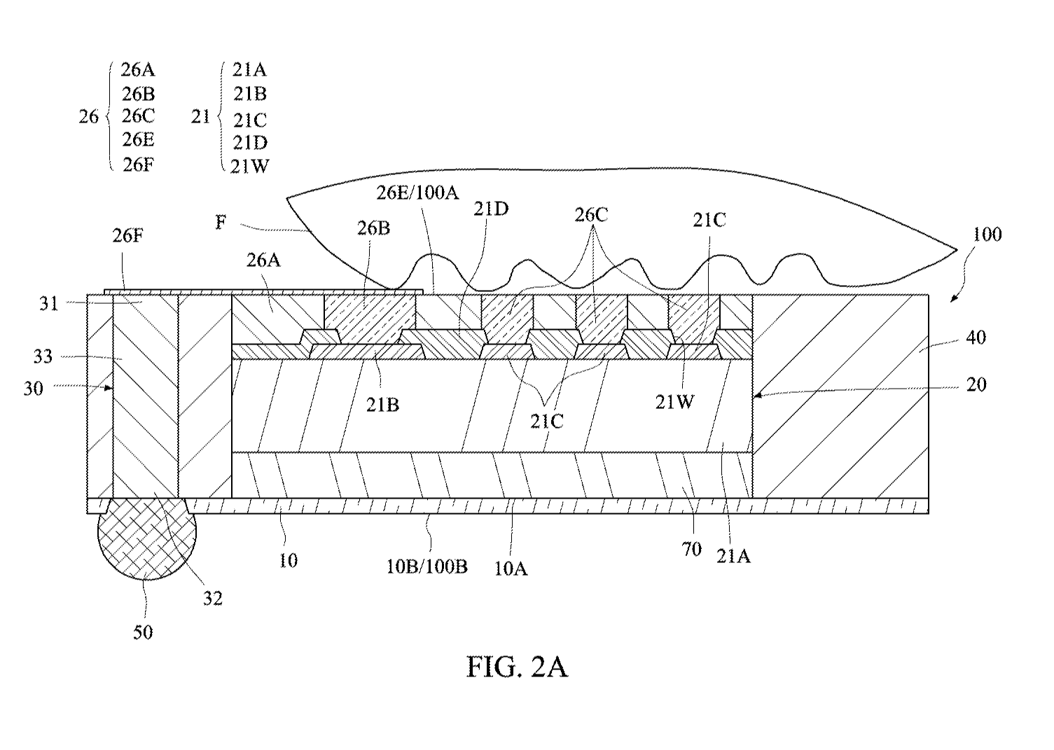

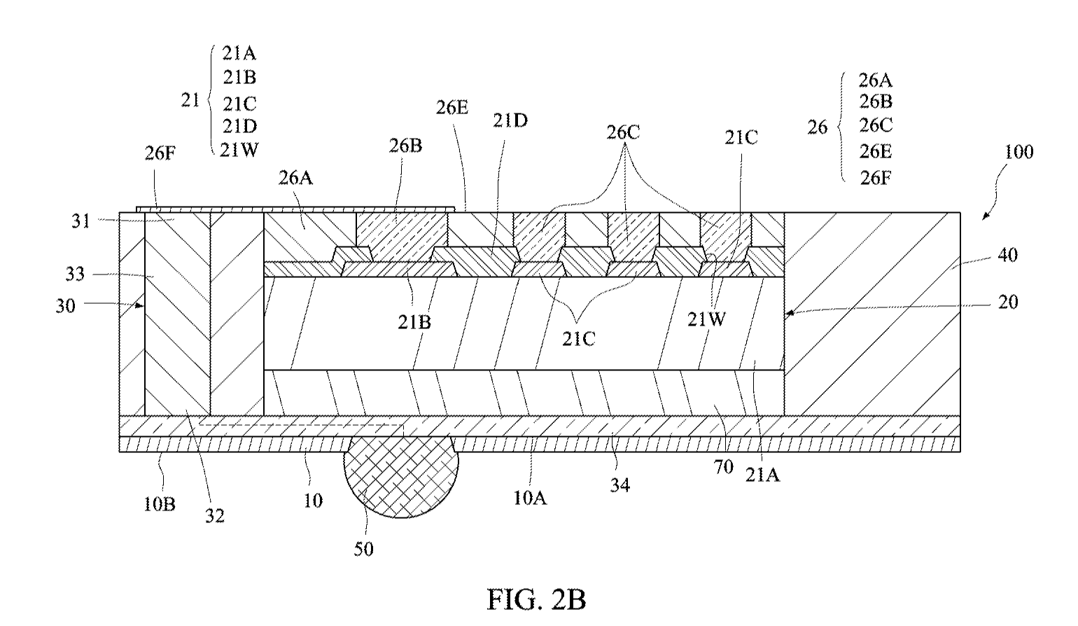

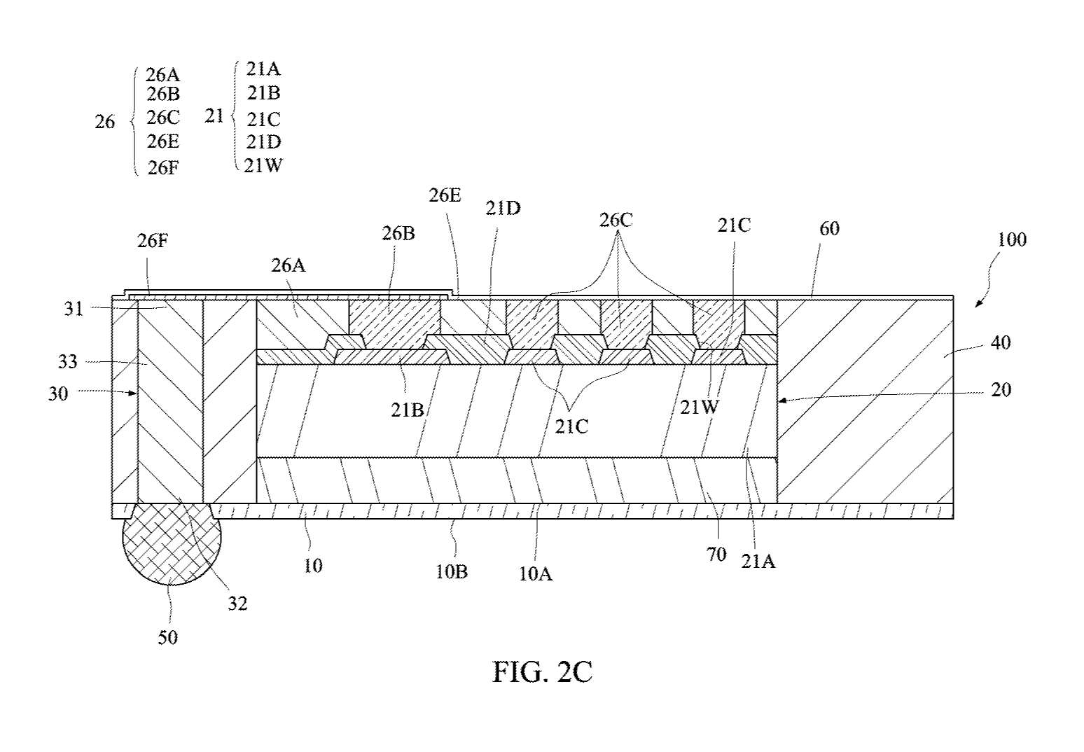

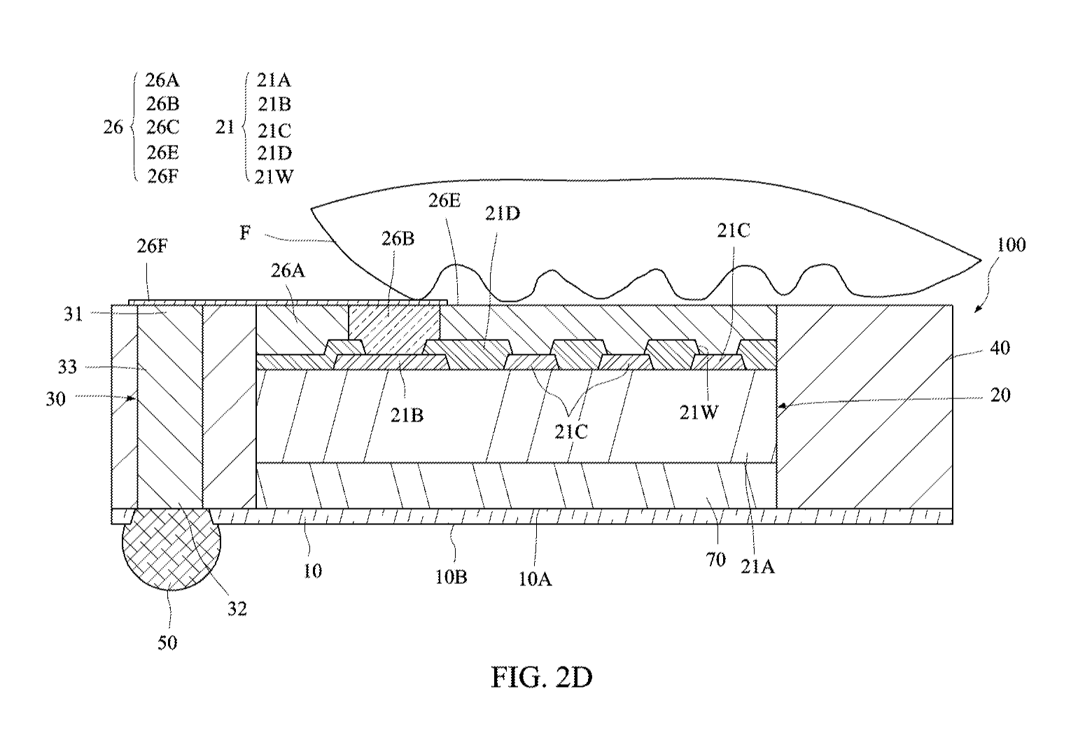

FIG. 2A is a schematic view showing a biometrics sensor 100 according to a first embodiment of the invention. Referring to FIG. 2A, the biometrics sensor 100 of this embodiment comprises a base 10, a biometrics sensing module 20, a signal transmission structure 30 and a molding layer 40.

The base 10 may be a package substrate made of the material, such as epoxy, polyimide, benzocyclobutene (BCB), polybenzoxazole (PBO) or analogues thereof. Alternatively, the material of the base may be an inorganic insulation material, such as glass, or a ceramics material, such as aluminum oxide, or the like.

The biometrics sensing module 20 is disposed on an upper surface 10A of the base 10, and comprises a biometrics sensing chip 21 and a signal extending structure 26. It is worth noting that the signal extending structure of the invention is a horizontally arranged structure, which mainly transmits the signal outwardly in the horizontal direction although a vertically arranged section is present. In addition, the signal extending structure is different from the conventional wire-bond connection structure, and has no arc section as compared with the conventional wire-bond and protection package layer, so that an all-flat finger contact surface can be provided, the ease of use can be completely highlighted, and the image sensing quality can be enhanced. In this embodiment, the biometrics sensing module 20 is disposed on the base 10 through an isolation layer 70, which is a die attach film (DAF) in this embodiment. However, the invention is not restricted thereto. In addition, the biometrics sensing module 20 of this embodiment is a finger sensor, such as a biometrics sensor for sensing the fingerprint, vein distribution image or blood oxygen concentration. However, the invention is not restricted thereto. The signal extending structure 26 is disposed on and electrically connected to the biometrics sensing chip 21. The signal extending structure 26 and the biometrics sensing chip 21 functionally link with each other to sense a fine biometrics characteristic of an organism F, contacting or approaching the biometrics sensing chip 21, to obtain a biometrics signal. Of course, the biometrics sensing chip 21 may have a signal processing circuit for controlling operations and processing the obtained biometrics signal into the processed signal to be outputted to another module for processing.

In this embodiment, the biometrics sensing chip 21 comprises a substrate 21A, connection pads 21B, sensing electrodes 21C and a chip protection layer 21D. The substrate 21A is, for example but without limitation to, a semiconductor substrate, such as a silicon substrate. The connection pads 21B and the sensing electrodes 21C are formed on the substrate 21A. The connection pads 21B are provided for the purpose of signal input and output, and the sensing electrodes 21C are the outermost exposed portions of the sensing members and for sensing the finger's biometrics information, such as the distances from the ridges to the sensing members by way of capacitor sensing, electric field sensing, piezoelectric sensing technology. Of course, the thermal induction method may serve as the sensing principle. The chip protection layer 21D is formed on the substrate 21A, partially covers the sensing electrodes 21C and the connection pads 21B, and has windows 21W through which the sensing electrodes 21C and the connection pads 21B are partially exposed from the chip protection layer 21D. Of course, in the practical application, a corresponding sensing member circuit and other corresponding signal processing circuits, such as an amplifier, an analog-to-digital converter and an associated digital control circuit (not shown) are usually disposed under each sensing electrode. Since this is well known by those skilled in the art, detailed descriptions thereof will be omitted. Only the main characteristic of the invention is described to make those skilled in the art be able to implement the invention.

The signal transmission structure 30 is disposed on the base 10 and one side or sides of the biometrics sensing module 20, and has a first connection end 31 electrically connected to the signal extending structure 26, and a second connection end 32 near the base 10. In this embodiment, the second connection end 32 is exposed from the base 10 (may also be regarded as landed on the base 10). It is worth noting that the number of the signal transmission structure(s) 30 corresponds to (but is not necessary to be the same as) the number of the connection pad(s) 21B. In addition, the traces may be designed according to the integrated circuit layout. Thus, the drawing only shows the state of one single cross-section.

The signal extending structure 26 comprises a second molding layer 26A, first outward extending electrodes 26B and second outward extending electrodes 26C embedded into the second molding layer 26A, and a horizontally outwardly expanded connection structure 26F. The horizontal direction is described in contrast to the horizontally arranged sensing electrodes 21C. Thus, if the sensing electrodes 21C are disposed on a first plane, then the outwardly expanded connection structures 26F are disposed on a second plane parallel to the first plane. The first outward extending electrodes 26B are disposed on the connection pads 21B, respectively, to achieve the electrically connections. The second outward extending electrodes 26C are disposed on the sensing electrodes 21C, respectively, to achieve the electrical connections. The outwardly expanded connection structures 26F electrically connect the connection pads 21B to the signal transmission structure 30. Thus, the biometrics signal is transmitted from the biometrics sensing module 20 to the second connection end 32. That is, the biometrics signal is transmitted from the top side of the biometrics sensing chip 21 to the peripheral side. In some embodiments, the outwardly expanded connection structures 26F may also be connected to the second outward extending electrodes 26C, so that the sensing members are extended to the locations above the peripheral molding layer 40, and the sensing members can have a new layout effect, especially the fan-out effect. Thus, the area of the sensing chip formed with the sensing members can be effectively reduced, and the cost can be decreased.

The molding layer 40 is connected to the base 10, the biometrics sensing module 20 and the signal transmission structure 30 with an upper surface 26E of the signal extending structure 26 being exposed from the molding layer 40, so that a sensing surface 100A of the biometrics sensor for sensing the finger, and an electrical signal interface 100B for inputting and outputting the electrical signals are disposed on a front side and a back side of the biometrics sensor 100, and are not disposed on the same side.

In addition, the biometrics sensor 100 may further comprise a signal output structure 50 electrically connected to the second connection end 32 and disposed on the base 10. Thus, the biometrics signal can be transmitted from the signal transmission structure 30 downward to the bottom side of the biometrics sensing chip 21. In this exemplified but non-restrictive embodiment, the signal output structure 50 is in the form of solder balls disposed on a lower surface 10B of the base 10.

In this embodiment, because the biometrics signal can be transmitted from the top side of the biometrics sensing chip 21 to the peripheral side through the extending structure 26, and then to the bottom side of the biometrics sensing chip 21 through the vertical signal transmission structure 30, the conventional wire-bonding process can be eliminated. The first advantage of such the design is to achieve the effect that the sensing surface and the electrical signal interface are substantially disposed on the front side and the back side of the sensing chip, so that the peripheral wire-bond package layer 540 interfering with the finger's contact, as shown in the example of FIG. 1A, can be avoided. This can provide an all-flat sensor design to provide the optimum sensing quality upon being contacted by the finger. The second advantage of such the design is that all manufacturing processes adopt the semiconductor wafer manufacturing processes and methods, so that all the trace designs can be minimized, and the overall area of the sensor can be reduced to achieve the slim and light advantages and to decrease the manufacturing cost. Furthermore, because the second outward extending electrode 26C can be extended from the sensing electrode 21C upwardly to serve as the sensing member, the distance from the sensing member to the finger can be shortened, thereby effectively enhancing the sensitivity and image quality.

FIG. 2B is a schematic view showing a biometrics sensor according to a second embodiment of the invention. As shown in FIG. 2B, this embodiment is similar to the first embodiment except that the signal transmission structure 30 of this embodiment comprises a conductor layer 33 and a redistribution layer 34. The conductor layer 33 is electrically connected to the signal output structure 50 through traces of the redistribution layer 34. The redistribution layer 34 has redistribution traces (not shown), which mainly redistributes the trace layout to form the signal output structure 50 at the suitable places for the subsequent mounting and electrically connecting purposes. Because the redistribution layer 34 has been widely applied to the semiconductor integrated circuit product, detailed descriptions thereof will be omitted. It is worth noting that in the embodiment of the invention, only the partial cross-sectional view is illustrated. Upon implementation, the signal transmission structure 30 and the signal output structure 50 may be symmetrically disposed on the left and right sides or on the front, rear, left and right sides.

FIG. 2C is a schematic view showing a biometrics sensor according to the third embodiment of the invention. Referring to FIG. 2C, this embodiment is similar to the first embodiment except that the biometrics sensor 100 further comprises an external protection layer 60 covering the signal extending structure 26 and the molding layer 40 to protect the signal extending structure 26 and the molding layer 40. More specifically, the external protection layer 60 covers the outwardly expanded connection structures 26F, the second molding layer 26A, the first outward extending electrodes 26B and the second outward extending electrodes 26C. Thus, the effect of protecting the exposed electrodes can be achieved.

FIG. 2D is a schematic view showing a biometrics sensor according to a fourth embodiment of the invention. As shown in FIG. 2D, this embodiment is similar to the first embodiment except that no second outward extending electrode 26C is provided. Thus, the biometrics sensing chip 21 comprises a substrate 21A, connection pads 21B and a chip protection layer 21D. The connection pad 21B is formed on the substrate 21A. The chip protection layer 21D is formed on the substrate 21A, partially covers the sensing electrodes 21C, entirely covers the connection pads 21B, and has windows 21W through which the connection pads 21B are partially exposed from the chip protection layer 21D. In addition, the signal extending structure 26 comprises a second molding layer 26A, and outward extending electrodes 26B and an outwardly expanded connection structure 26F embedded into the second molding layer 26A. The outward extending electrodes 26B are disposed on the connection pads 21B, respectively. The outwardly expanded connection structure 26F electrically connects the connection pads 21B to the signal transmission structure 30. With this structure, the effect similar to that of the first embodiment still can be achieved.

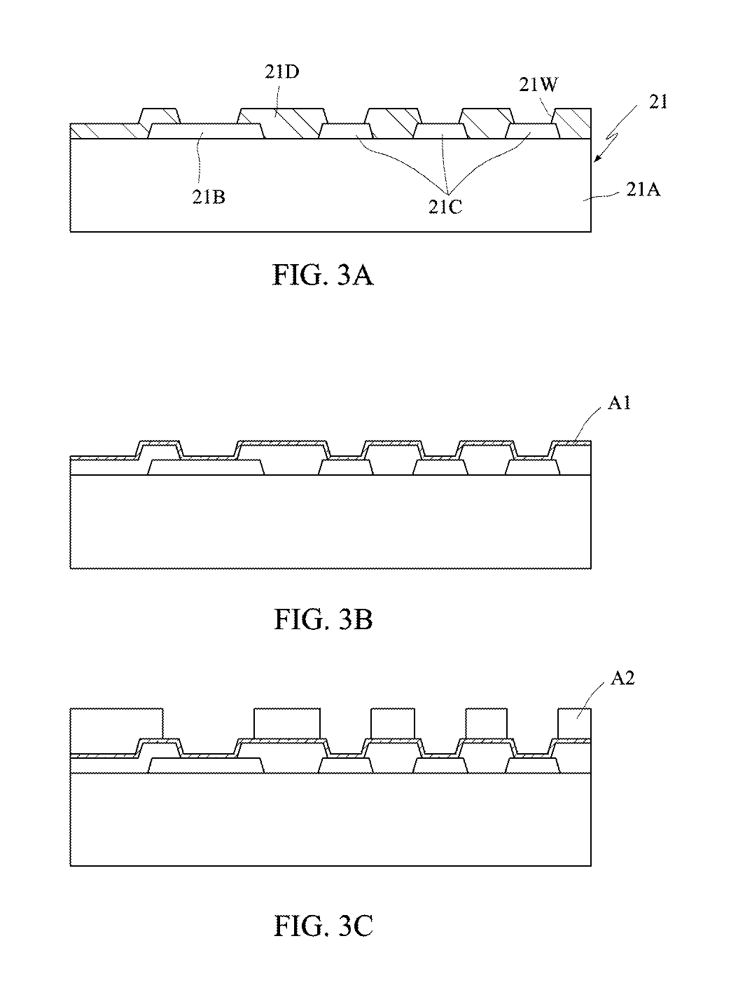

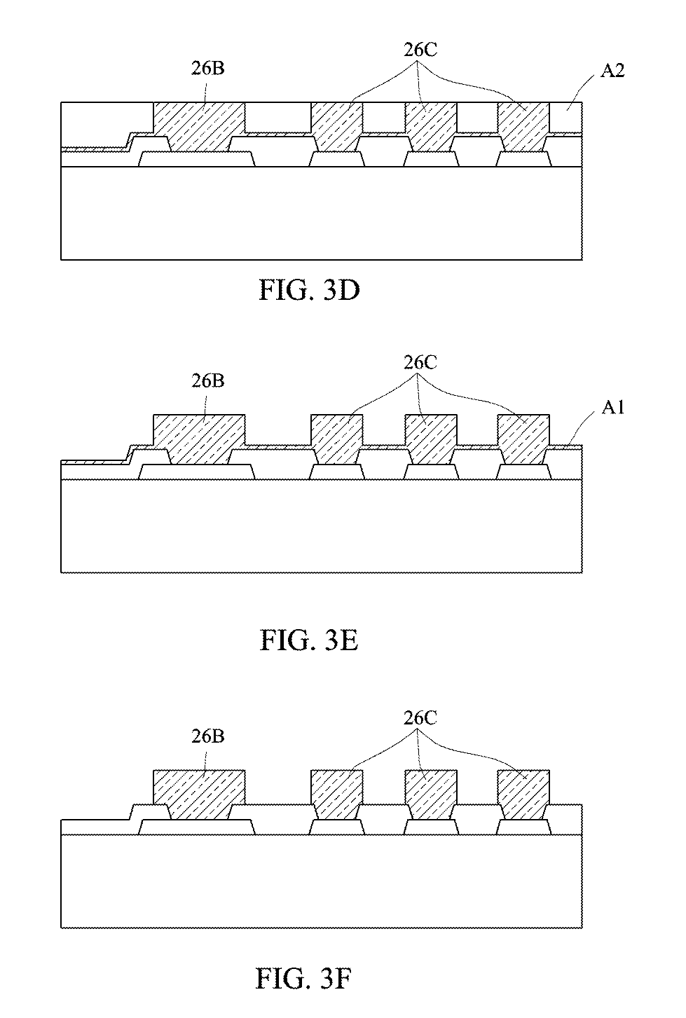

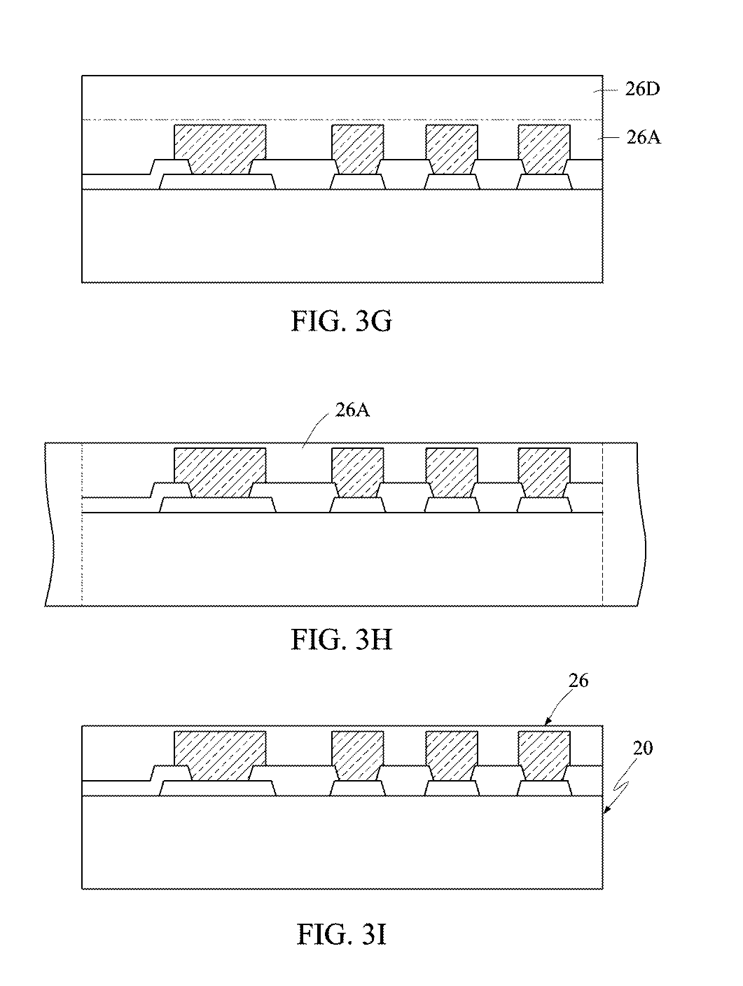

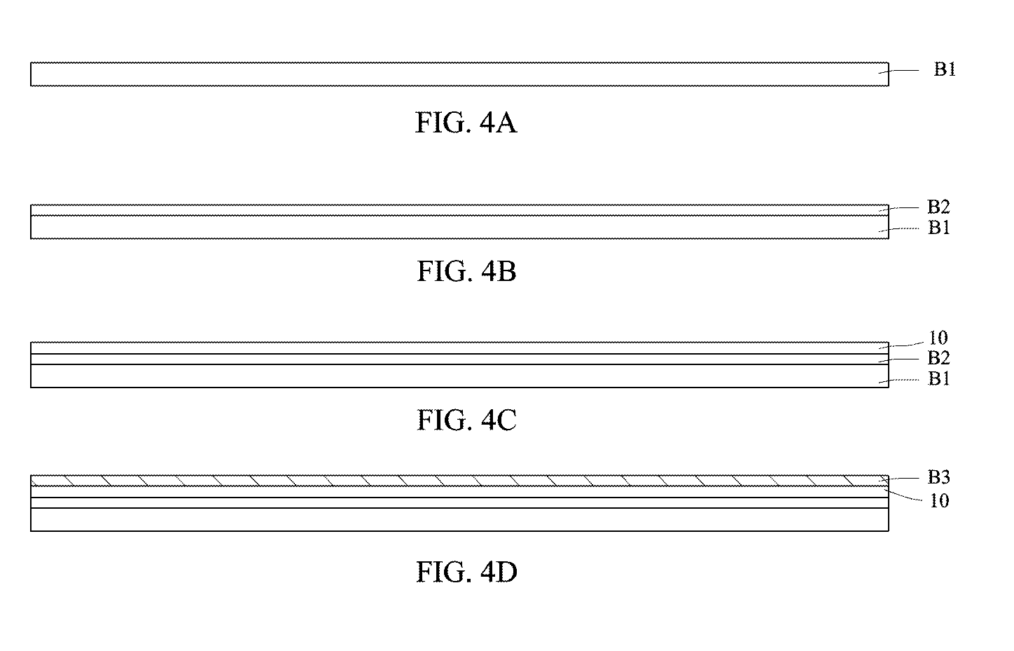

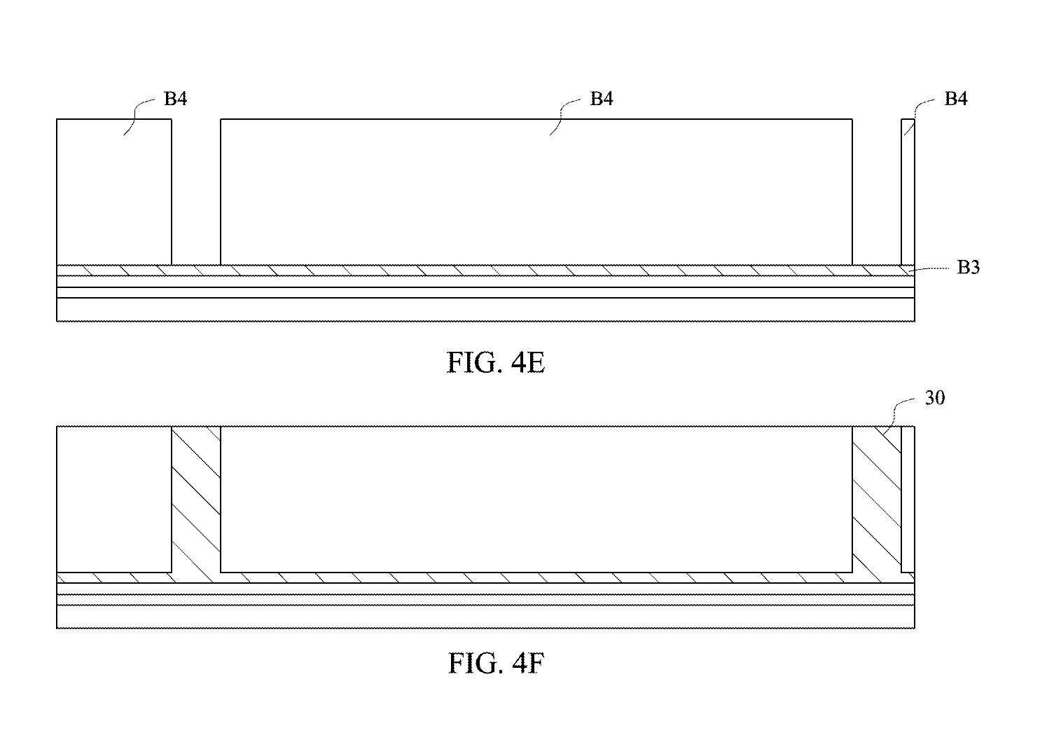

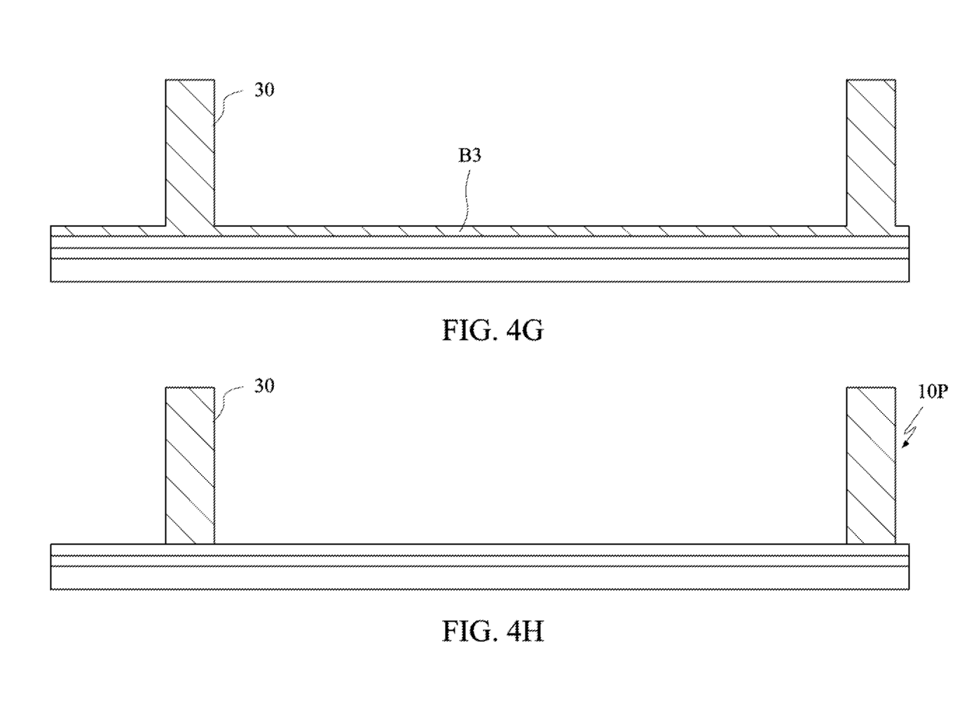

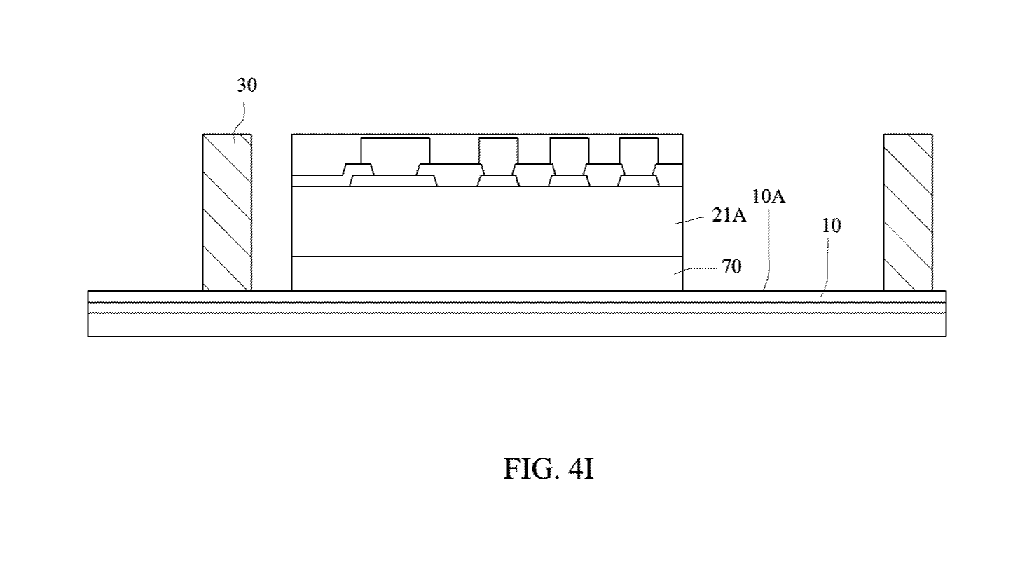

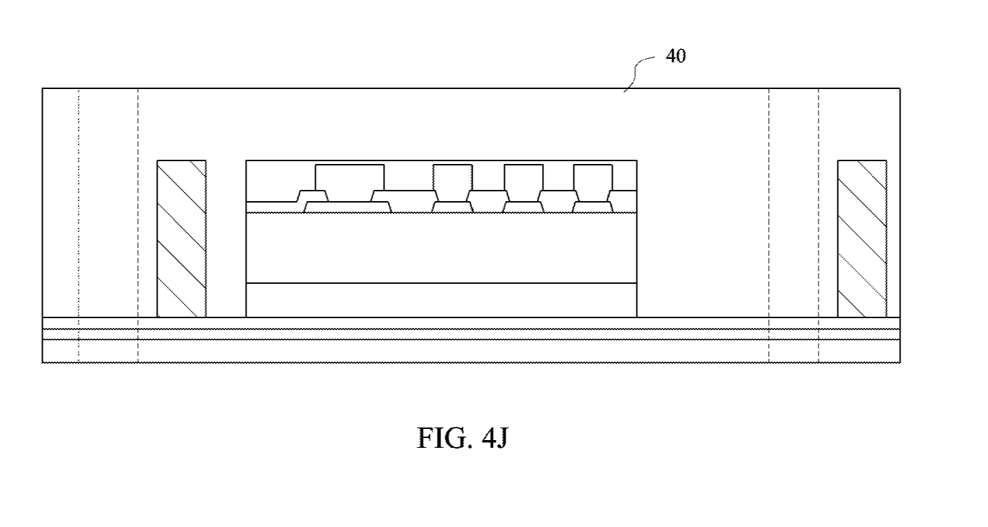

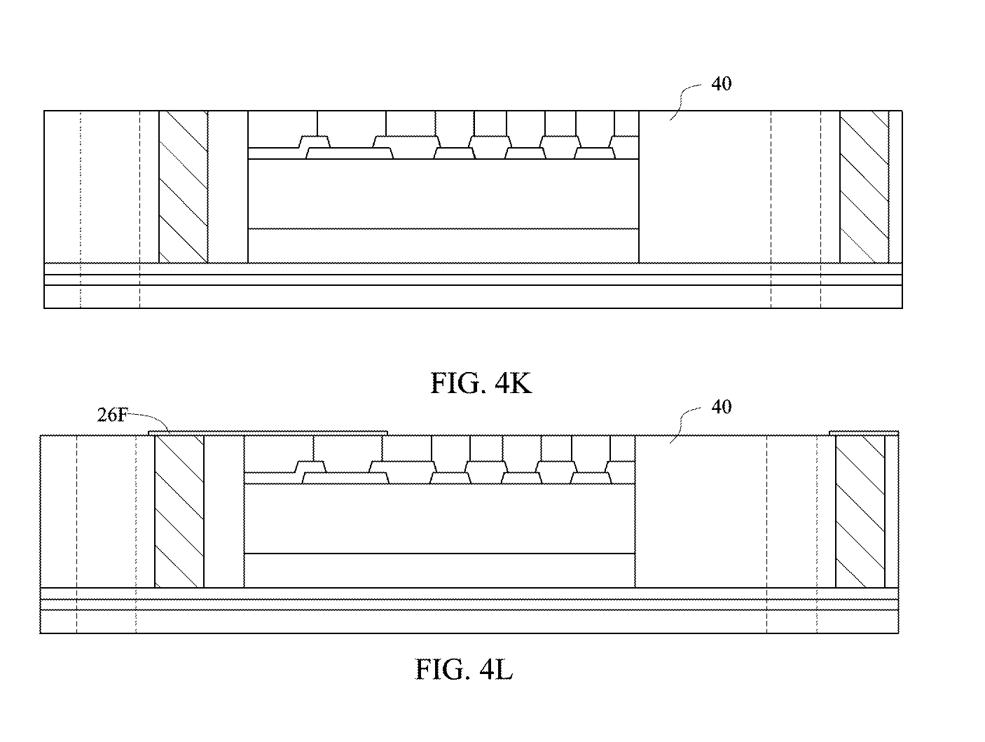

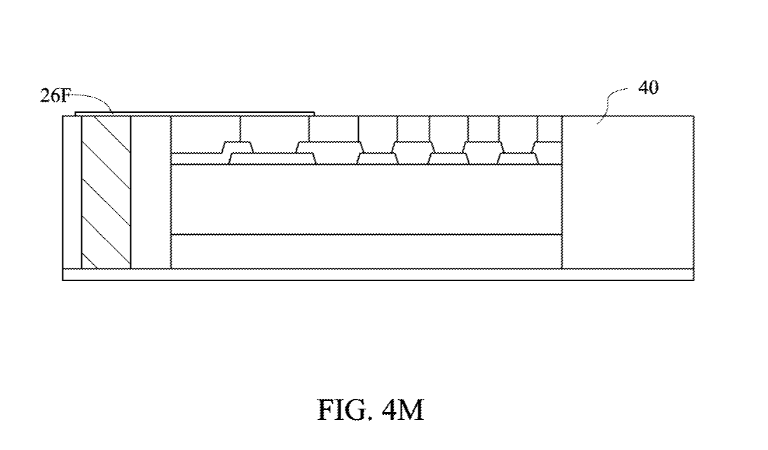

FIGS. 3A to 3I are FIGS. 4A to 4O are schematic views showing structures in steps of the method of manufacturing the biometrics sensor according to the first embodiment of the invention.

First, in step (a), the biometrics sensing chip 21 is provided, as shown in FIG. 3A. Next, in step (b), one portion of the signal extending structure 26 is formed on the biometrics sensing chip 21 to constitute one portion of the biometrics sensing module 20, as shown in FIGS. 3B to 3I. Then, in step (c), a base structure 10P having the base 10 and the signal transmission structure 30 disposed on the base 10 is provided, as shown in FIGS. 4A to 4H. Next, in step (d), the portion of the biometrics sensing module 20 is disposed on an upper surface 10A of the base 10, so that the signal transmission structure 30 is disposed on one side or sides of the biometrics sensing module 20, as shown in FIG. 4I. Then, in step (e), the molding layer 40 is connected to the base 10, the portion of the biometrics sensing module 20 and the signal transmission structure 30 with the portion of the signal extending structure 26 being exposed from the molding layer 40, as shown in FIGS. 4J to 4K. It is worth noting that the associated symbols can be understood with reference to FIG. 2A, so only some symbols are shown in FIGS. 3A to 3I and FIGS. 4A to 4O.

Next, in step (f), the other portion of the signal extending structure 26 is formed to electrically connect the portion of the signal extending structure 26 to the signal transmission structure 30, as shown in FIG. 4L. Thus, the signal extending structure 26 and the biometrics sensing chip 21 functionally link with each other to sense fine biometrics characteristics of the organism F, contacting or approaching the biometrics sensing chip 21, to obtain the biometrics signal transmitted to the signal transmission structure 30. In a non-limitative example, the organism F contacts or approaches the signal extending structure 26.

In addition, the manufacturing method further comprises the following steps. In step (g), the signal output structure 50 electrically connected to the second connection end 32 is formed on the base 10.

In FIG. 3A, the biometrics sensing chip 21 comprises the substrate 21A; the connection pads 21B and the sensing electrodes 21C formed on the substrate 21A; and the chip protection layer 21D, which is formed on the substrate 21A, partially covers the sensing electrodes 21C and the connection pads 21B, and has the windows 21W through which the sensing electrodes 21C and the connection pads 21B are partially exposed from the chip protection layer 21D. In fact, the schematic structure of FIG. 3A is the structure of the manufacturing process of a standard semiconductor integrated circuit. FIG. 3A only shows the outermost metal structure (i.e., the connection pads 21B and the sensing electrodes 21C) and the protection layer 21D covering the outermost metal structure, wherein the integrated circuit manufacturing processes and structures of the other portions can be easily understood by those skilled in the art and will not be described herein.

As shown in FIG. 3B, the step (b) comprises the following steps. First, in step (b1), a seed layer A1 is formed on the chip protection layer 21D, the connection pads 21B and the sensing electrodes 21C, wherein the material of the seed layer mainly includes Cu or Ti/Cu, and the seed layer is the metal layer formed by way of physical vapor deposition to have a thickness of about several hundreds of angstroms. Then, in step (b2), as shown in FIG. 3C, a patterned resist layer A2 is formed on the seed layer A1 to partially expose the seed layer A1. Next, in step (b3), the copper electroplating is performed using the partially exposed seed layer A1, as shown in FIG. 3D, wherein the electroplating height is greater than or equal to 5 microns (um) and is preferably equal to 15 um. Of course, the copper electroplating is performed in conjunction with the above-mentioned copper seed layer. However, the invention is not restricted thereto, and any current or future similar process can be applied to the invention without departing from the spirit or scope of the invention. Then, in step (b4), the patterned resist layer A2 is removed (FIG. 3E) and a portion of the seed layer A1 is removed (FIG. 3F) to form first outward extending electrodes 26B and second outward extending electrodes 26C, as shown in FIGS. 3E and 3F. Next, in step (b5), an insulation material (e.g., a molding compound) is provided to form a second molding layer 26A and a sacrificial protection layer 26D (both of them are actually an integrated structure) for embedding the first outward extending electrodes 26B and the second outward extending electrodes 26C into the second molding layer 26A. That is, the first outward extending electrodes 26B and the second outward extending electrodes 26C are embedded into an integrally formed second molding layer 26A and sacrificial protection layer 26D, as shown in FIG. 3G, wherein the insulation material may be epoxy, polyimide, benzocyclobutene (BCB), polybenzoxazole (PBO) or analogues thereof. Of course, the insulation material may be silicon oxide, silicon nitride or the like, which is frequently used in the integrated circuit manufacturing process to form the insulating layer. Then, in step (b6), the sacrificial protection layer 26D is removed while the second molding layer 26A is left, as shown in FIG. 3H. Of course, the molding compound removing operation may be performed in the following steps of FIGS. 4J to 4K to decrease the number of steps. So, this can be resiliently used without being restricted to the description of the embodiment of this drawing. It is worth noting that FIG. 3H is the result obtained after the molding compound is ground back, while FIG. 3I is the result obtained after multiple biometrics sensing modules are diced (along the dashed lines of FIG. 3H). That is, the manufacturing processes of FIGS. 3A to 3G are the wafer-based production flows, which meet the mass production and the automatic production, and are prepared with respect to the mass production of the biometrics sensing modules 20. The associated structures can be easily understood by those skilled in the art, so detailed descriptions thereof will be omitted.

In addition, the second molding layer 26A of FIG. 3H covers the first outward extending electrode 26B and the second outward extending electrode 26C. In another example, however, the first outward extending electrode 26B and the second outward extending electrode 26C may also be exposed from the second molding layer 26A. Furthermore, in still another embodiment, the steps of FIGS. 3G and 3H can be directly omitted, and the structure of FIG. 3I can be directly manufactured using a mold without the formation of the sacrificial protection layer 26D and without the removing of the sacrificial protection layer 26D. Alternatively, the steps of FIGS. 3G and 3H can be directly omitted, and the structure of exposing the first outward extending electrode 26B and the second outward extending electrode 26C can be directly formed using the mold.

After the formation of the biometrics sensing module 20, one single or multiple biometrics sensing modules 20 can be used to perform the manufacturing steps of FIGS. 4A to 4O. Thus, the step (c) comprises the following steps. First, in step (c1), the base 10 is disposed on a carrier wafer B1, as shown in FIGS. 4A to 4C. The carrier wafer B1 comprises, without limitation to, a glass wafer. In FIG. 4B, an adhesive layer B2, such as light-to-heat conversion (LTHC) layer, is coated on the carrier wafer B1. Then, the base 10 is formed on the adhesive layer B2. Next, in step (c2), a seed layer B3 is formed on the base 10, wherein the material of the seed layer B3 may be the same as the material of the seed layer A1, as shown in FIG. 4D. Then, in step (c3), a patterned resist layer B4 is formed on the seed layer B3 to partially expose the seed layer B3, as shown in FIG. 4E. Next, in step (c4), electroplating is performed using the partially exposed seed layer B3, as shown in FIG. 4F. Then, in step (c5), the patterned resist layer B4 (FIG. 4G) and a portion of the seed layer B3 (FIG. 4H) are removed to form the signal transmission structure 30. In this embodiment, the height of the signal transmission structure is equal to at least 50 um, preferably equal to about 150 um, and the material is the same as that of the first outward extending electrode 26B. It is worth noting that the one portion of the seed layer B3 has been integrated with the signal transmission structure 30 in the electroplating process. Then, the step (d) will be performed. Next, the molding compound manufacturing process is performed to form the molding layer 40, as shown in FIG. 4J. Then, the molding layer 40 is ground back until the signal transmission structure 30, the second molding layer 26A, the first outward extending electrode 26B and the second outward extending electrode 26C are exposed, as shown in FIG. 4K. The signal transmission structure 30, the second molding layer 26A, the first outward extending electrode 26B and the second outward extending electrode 26C are disposed on the same horizontal plane. It is worth noting that the dashed line after FIG. 4J represents the scribing line. In addition, FIG. 4J may be omitted, and the structure of FIG. 4K is directly manufacturing using the mold without the grinding step. At this time, the first outward extending electrode 26B and the second outward extending electrode 26C have been exposed in the stage of FIG. 3I. Next, the outwardly expanded connection structure 26F of the signal extending structure 26 is formed by way of electroplating, display printing, coating or the like, wherein the material of the extending structure may be any metal conductor, such as aluminum, copper, gold or the like, as shown in FIG. 4L. Then, the glass carrier is separated from the base 10 by the laser peel off process according to the property of the LTHC material. Next, dicing is performed along the scribing line to form the structure as shown in FIG. 4M. Finally, the step (g) can be performed to form a signal output structure 50, electrically connected to the second connection end 32, on the base 10. That is, a window 10W is formed on the base 10 to expose the signal transmission structure 30, as shown in FIG. 4N. Then, the signal transmission structure 30 is formed in the window 10W, as shown in FIG. 4O.

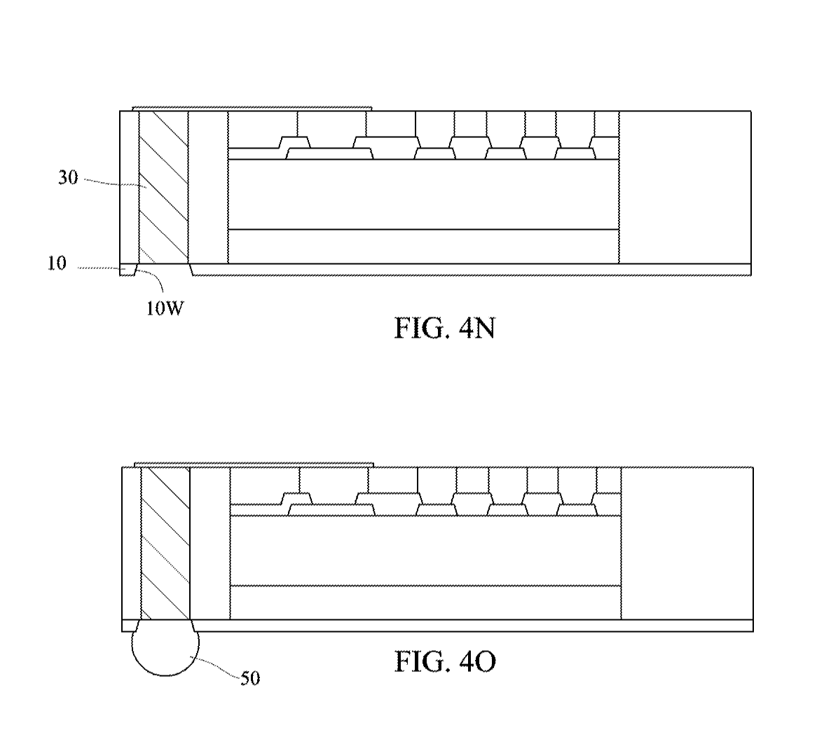

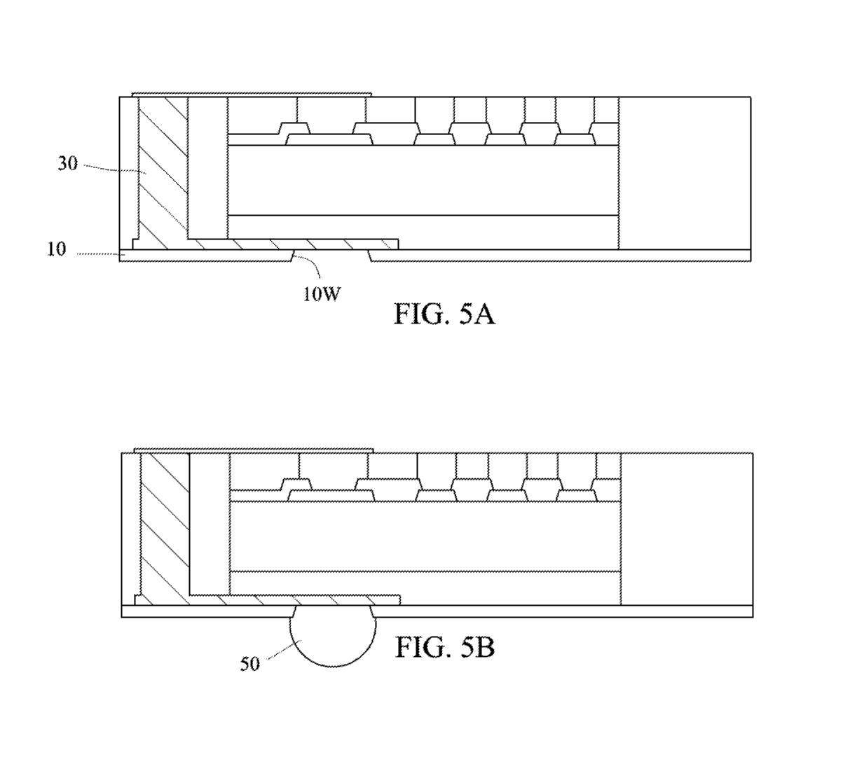

The method of manufacturing the structure of FIG. 2B is similar to the method of manufacturing the structure of FIG. 2A except for the redistribution layer 34, which makes the signal transmission structure 30 have the L-shaped cross-section. The redistribution layer may be defined by way of lithography or electroplating so that the bottom horizontal section of the L-shaped cross-section is formed, and then another electroplating is performed to form the vertical section. Thus, the step (c) of the manufacturing method of this embodiment comprises the following steps of: (c1) forming the redistribution layer 34 on the carrier wafer B1 and disposing the base 10 on the redistribution layer 34; (c2) forming a seed layer B3, electrically connected to the redistribution layer 34, on the base 10; (c3) forming a patterned resist layer B4 on the seed layer B3 to partially expose the seed layer B3; (c4) performing electroplating using the partially exposed seed layer B3; and (c5) removing the patterned resist layer B4 and a portion of the seed layer B3 to form the signal transmission structure 30. Finally, in step (g), a signal output structure 50, electrically connected to the redistribution layer 34, is formed on the base 10. Regarding the manufacturing processes, FIGS. 5A and 5B may be compared with FIGS. 4N and 40, wherein the position of the window 10W of FIG. 5A is slightly different from the position of the window 10W of FIG. 4N. The details can be easily understood by those skilled in the art according to FIG. 2B, FIG. 3A to 4O and FIGS. 5A and 5B, so detailed descriptions thereof will be omitted.

The manufacturing method of the structure of FIG. 2C is similar to the manufacturing method of the structure of FIG. 2A except that the last step is to form the external protection layer 60.

The manufacturing method of the structure of FIG. 2D is similar to the manufacturing method of the structure of FIG. 2A except that no second outward extending electrode 26C is formed. Thus, the step (b) comprises the following steps of: (b1) forming a seed layer A1 on the chip protection layer 21D and the connection pads 21B; (b2) forming a patterned resist layer A2 on the seed layer A1 to partially expose the seed layer A1; (b3) performing electroplating using the partially exposed seed layer A1; (b4) removing the patterned resist layer A2 and a portion of the seed layer A1 to form the outward extending electrodes 26B; and (b5) pouring a molding compound to form the second molding layer 26A. Of course, the external protection layer 60 as shown in FIG. 2C may further be formed on the outermost surface (not shown) to protect the outwardly expanded connection structure 26F.

In the embodiment where the grinding back is needed, the step (b) comprises the following steps of: (b1) forming a seed layer A1 on the chip protection layer 21D and the connection pads 21B; (b2) forming a patterned resist layer A2 on the seed layer A1 to partially expose the seed layer A1; (b3) performing electroplating using the partially exposed seed layer A1; (b4) removing the patterned resist layer A2 and a portion of the seed layer A1 to form the outward extending electrodes 26B; (b5) pouring a molding compound to form the chip protection layer 21D, the second molding layer 26A and the sacrificial protection layer 26D; and (b6) removing the sacrificial protection layer 26D with the second molding layer 26A being left.

Heretofore, the manufacturing processes shown in FIGS. 4A to 4O show the structures for those skilled in the art to implement the invention, and do not intend to restrict the manufacturing processes for forming the structures of the invention. Instead, the biometrics sensing chip 21 of FIG. 4I can be inverted (that is, the front side faces downwards), and the similar manufacturing processes can be performed to complete the structures of FIGS. 2A to 2D. For example, the signal output structure 50 and associated structures can be formed on the back side (top side) of the biometrics sensing chip 21, and then the signal transmission structure 30 is formed on the front side of the biometrics sensing chip 21.

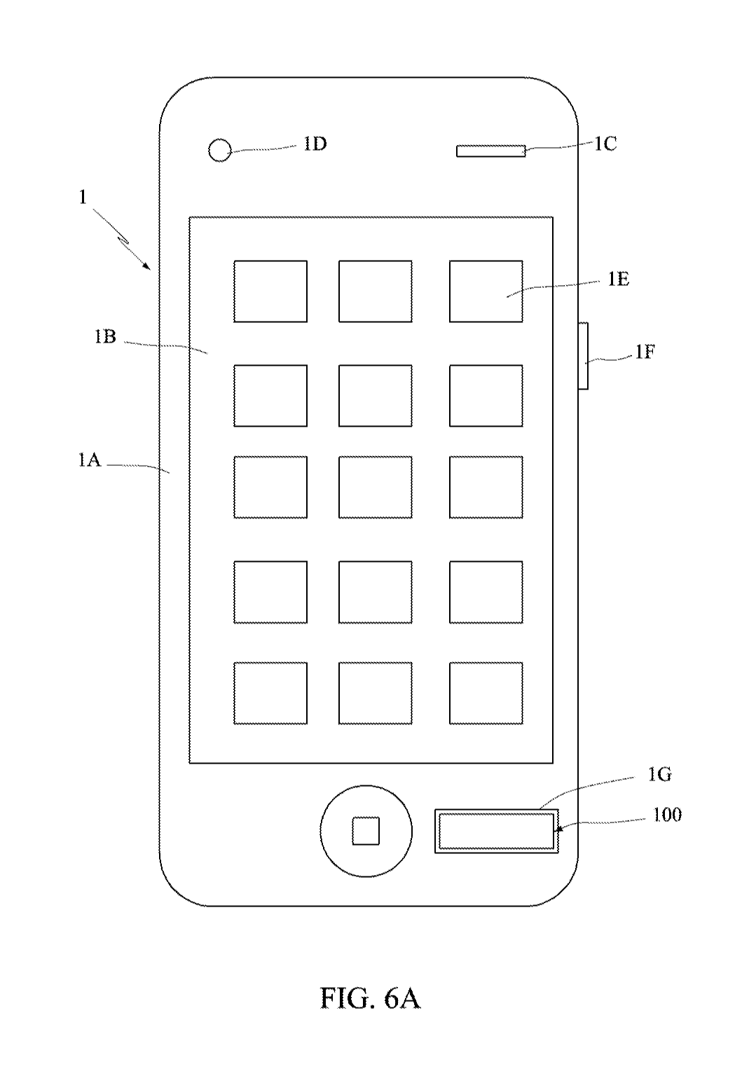

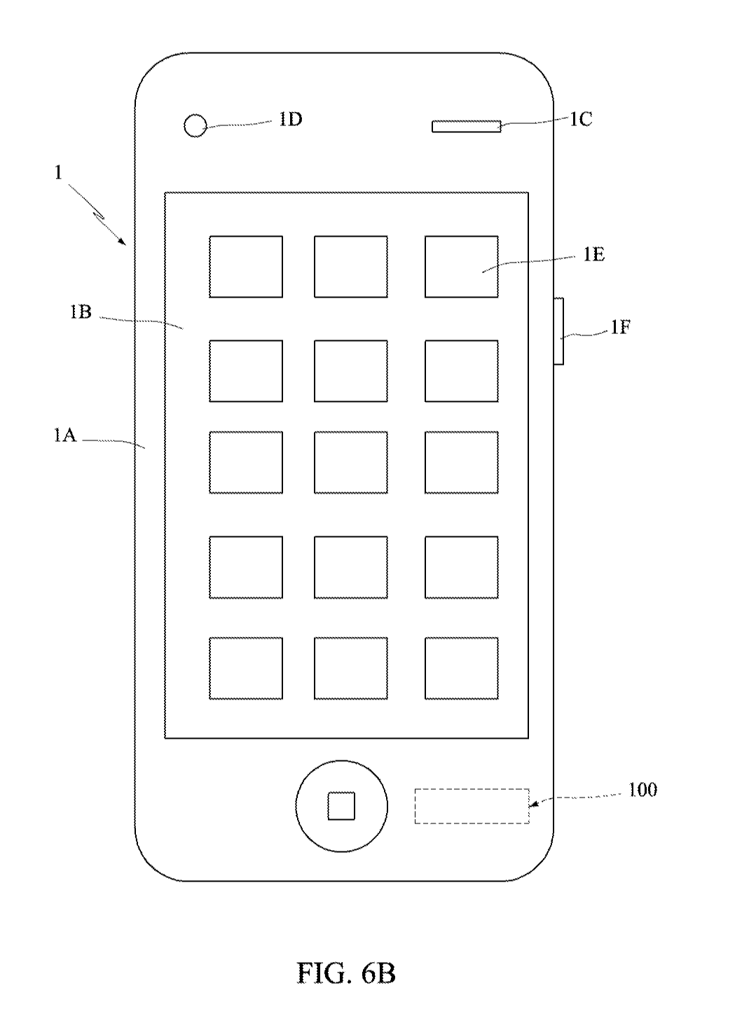

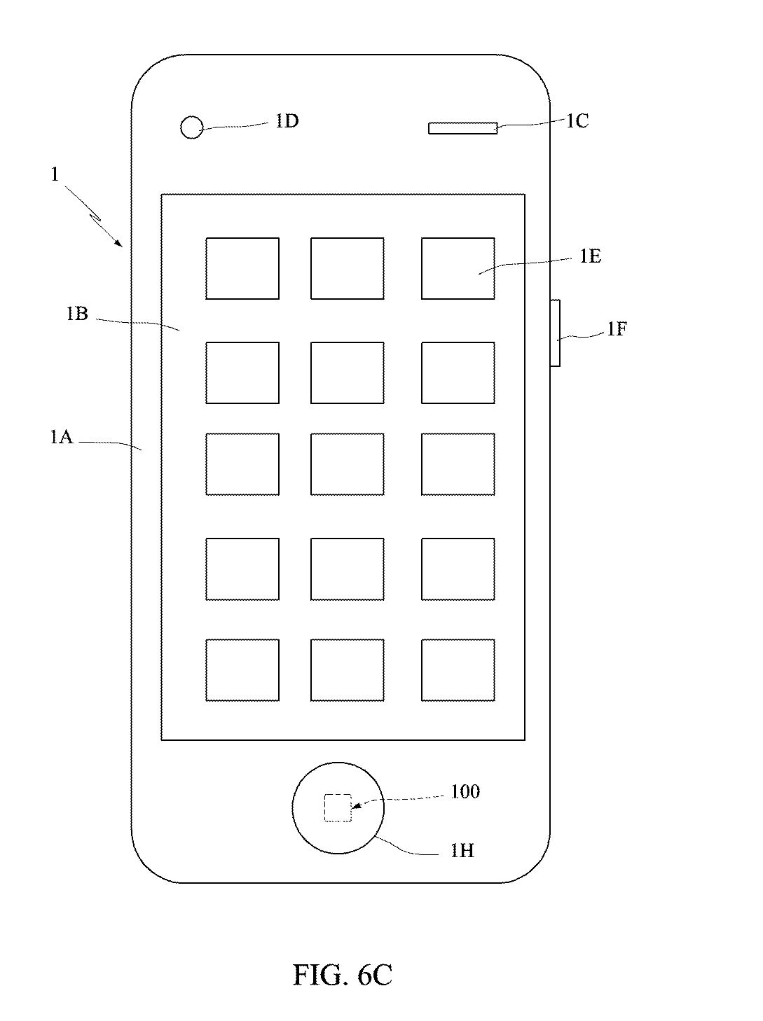

FIGS. 6A to 6C are schematic views showing three examples of electronic apparatuses using the biometrics sensor of the invention. As shown in FIG. 6A, a display 1B, a speaker 1C, a camera lens 1D and a switch 1F are mounted on a housing 1A of an electronic apparatus 1. Multiple touch icons 1E are displayed on the display 1B. The housing 1A is formed with a simple opening 1G, and the biometrics sensor 100 is mounted in the opening 1G without the slideway design. As shown in FIG. 6B, the biometrics sensor 100 having the all-flat design can be hidden under the housing 1A or the glass of the display. As shown in FIG. 6C, the biometrics sensor 100 having the all-flat design and configured into the small-area sensor can be hidden under the button 1H. This is the advantage of applying the all-flat biometrics sensor of the invention, and can make the product's outlook become more beautiful.

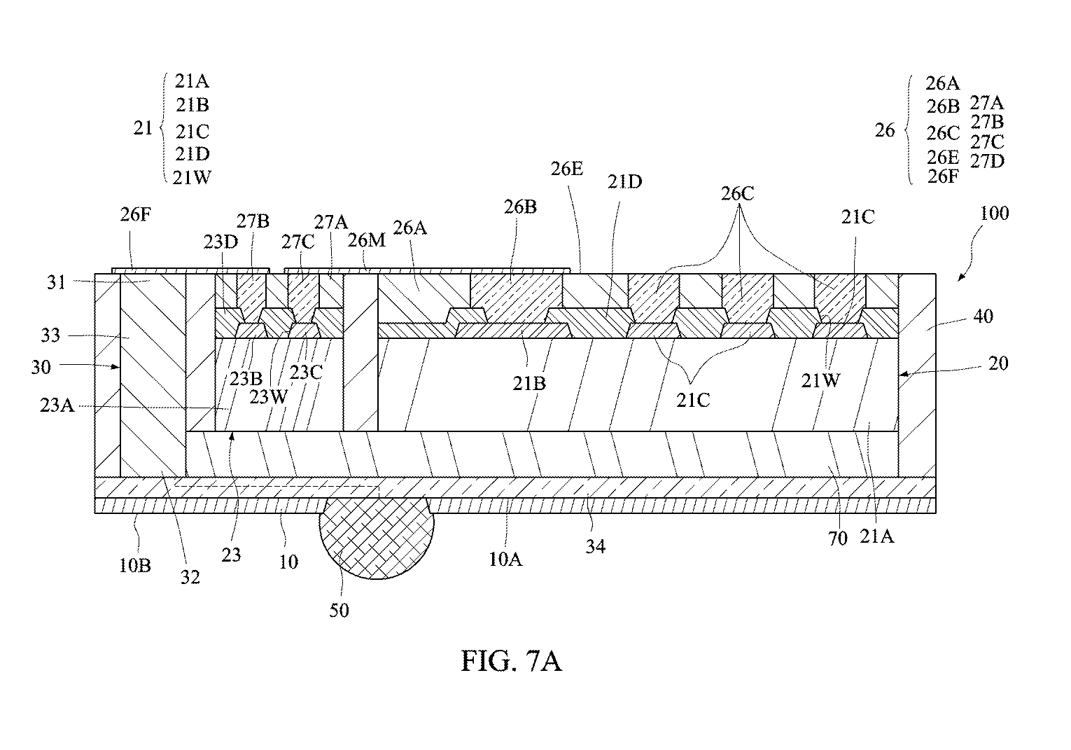

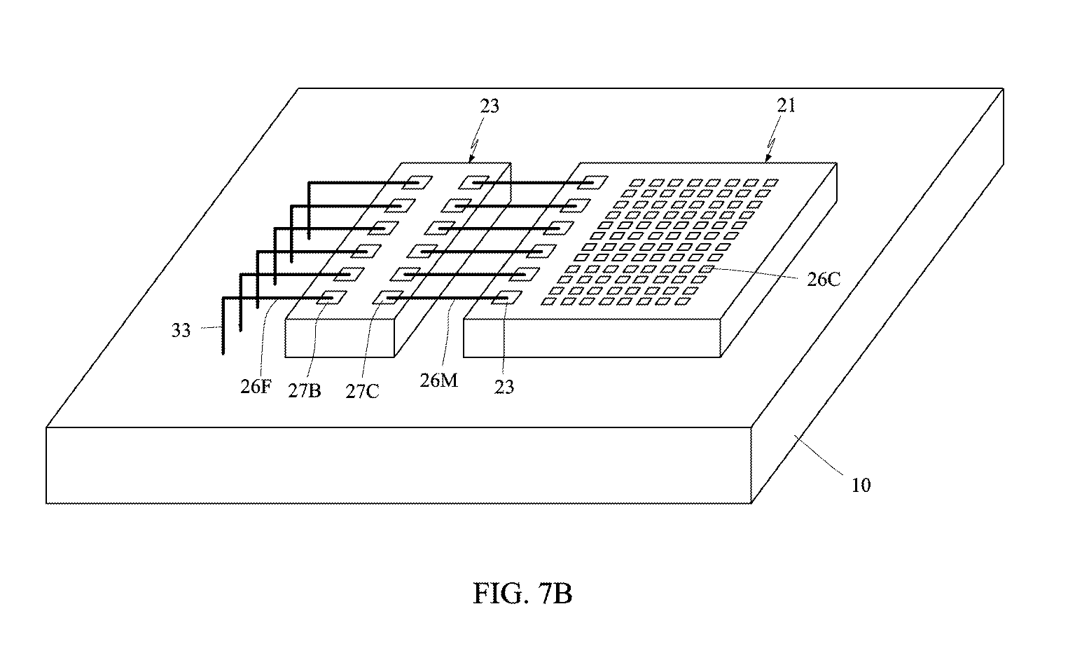

FIG. 7A is a schematic view showing a biometrics sensor according to a fifth embodiment of the invention. FIG. 7B is a partial pictorial view showing the biometrics sensor according to the fifth embodiment of the invention. In this embodiment, the separated biometrics sensing chip 21 and signal processing chip 23 are used to replace the biometrics sensing chip of the first embodiment. This is because that the manufacturing process of the signal processing chip 23 is different from that of the biometrics sensing chip 21. In general, the biometrics sensing chip 21 mainly aims at the analog signal processing and needs the low noise manufacturing process, while the signal processing chip 23 aims at the operating speed and needs the more advanced manufacturing process (with the narrower line width). If the two elements are integrated into one single chip, the cost is suddenly increased, and the signal quality may be sacrificed. Thus, what is different form the first to fourth embodiments is that the biometrics sensing chip 21 of this embodiment itself may not have the complicated signal processing function, such as an operation logic circuit having a fingerprint recognition algorithm or complicated encryption and decryption functions, and is only a standard input/output (I/O) interface, such as a SPI interface.

As shown in FIGS. 7A and 7B, the biometrics sensor 100 of this embodiment comprises a base 10, a biometrics sensing module 20, a signal transmission structure 30 and a molding layer 40.

The biometrics sensing module 20 disposed on an upper surface 10A of the base 10 comprises a biometrics sensing chip 21, a signal processing chip 23 and a signal extending structure 26. The signal extending structure 26 is disposed on and electrically connected to the biometrics sensing chip 21 and the signal processing chip 23. The signal extending structure 26 functionally links with the biometrics sensing chip 21 and the signal processing chip 23 to sense a fine biometrics characteristic (not whether the finger is touched or not) of an organism F, contacting or approaching the signal extending structure 26, to obtain a biometrics signal. The signal processing chip 23 receives and processes a sensing signal, coming from the biometrics sensing chip 21, to obtain the biometrics signal.

The signal transmission structure 30 disposed on the base 10 and one side or sides of the biometrics sensing module 20 has a first connection end 31 electrically connected to the signal extending structure 26, a second connection end 32 near the base 10, and a middle connection portion 26M electrically connected to the biometrics sensing chip 21 and the signal processing chip 23, so that the biometrics signal is transmitted from the biometrics sensing module 20 to the second connection end 32.

The molding layer 40 is connected to the base 10, the biometrics sensing module 20 (containing the biometrics sensing chip 21 and the signal processing chip 23) and the signal transmission structure 30 with an upper surface 26D of the signal extending structure 26 being exposed from the molding layer 40, so that a sensing surface and an electrical signal interface of the biometrics sensor are substantially disposed on a front side and a back side of the biometrics sensor, respectively.

In addition, the biometrics sensor 100 may further comprise a signal output structure 50 and an external protection layer 60. The signal transmission structure 30 comprises a conductor layer 33 and a redistribution layer 34. The biometrics sensing module 20 is disposed on the base 10 through a stopper layer 70. The biometrics sensing chip 21 comprises a substrate 21A and a chip protection layer 21D. These structures are similar to those of the first and fourth embodiments, so detailed descriptions thereof will be omitted. It is worth noting that the architecture adopting the two chips (biometrics sensing chip 21 and the signal processing chip 23) can be similarly applied to the first and fourth embodiments.

The signal processing chip 23 comprises: a substrate 23A; output connection pads 23B and input connection pads 23C formed on the substrate 23A; and a chip protection layer 23D formed on the substrate 23A, partially covering the input connection pads 23C and the output connection pads 23B, and having windows 23W through which the input connection pads 23C and the output connection pads 23B are partially exposed from the chip protection layer 23D.

In addition, the signal extending structure 26 further comprises: a second molding layer 26A and a third molding layer 27A; first outward extending electrodes 26B and second outward extending electrodes 26C embedded into the second molding layer 26A, and third outward extending electrodes 27B and fourth outward extending electrodes 27C embedded into the third molding layer 27A, wherein the first outward extending electrodes 26B are disposed on the connection pads 21B, respectively, the second outward extending electrodes 26C are disposed on the sensing electrodes 21C, respectively, the third outward extending electrodes 27B are disposed on the output connection pads 23B, respectively, and the fourth outward extending electrodes 27C are disposed on the input connection pads 23C; and an outwardly expanded connection structure 26F electrically connecting the output connection pads 23B to the signal transmission structure 30. Thus, the sensing signal of the biometrics sensing chip 21 can be inputted to the biometrics sensing chip 21 through the first outward extending electrode 26B, the middle connection portion 26M and the fourth outward extending electrodes 27C. The biometrics sensing chip 21 processes the sensing signal into the biometrics signal, which can be outputted to the outwardly expanded connection structure 26F through the third outward extending electrodes 27B, and finally outputted to the signal output structure 50. The middle connection portion 26M and the outwardly expanded connection structure 26F may be formed in the same manufacturing process.

The biometrics sensor 100 of the fifth embodiment may also be applied to the architecture of FIG. 2D. In this case, the signal processing chip 23 comprises: a substrate 23A; output connection pads 23B and input connection pads 23C formed on the substrate 23A; and a chip protection layer 23D, which is formed on the substrate 23A, partially covers the input connection pads 23C and the output connection pads 23B and has windows 23W through which the input connection pads 23C and the output connection pads 23B are partially exposed from the chip protection layer 23D. The signal extending structure 26 further comprises: a second molding layer 26A and a third molding layer 27A; outward extending electrodes 26B embedded into the second molding layer 26A, and third outward extending electrodes 27B and fourth outward extending electrodes 27C embedded into the third molding layer 27A, wherein the outward extending electrodes 26B are disposed on the connection pads 21B, respectively, the third outward extending electrodes 27B are disposed on the output connection pads 23B, respectively, and the fourth outward extending electrodes 27C are disposed on the input connection pads 23C, respectively; and an outwardly expanded connection structure 26F electrically connecting the output connection pads 23B to the signal transmission structure 30.

It is worth noting that the biometrics sensing chip 21 and the signal processing chip 23 are formed on different wafers, and then disposed on the base 10 to perform the electrical connection and package processes. The methods of forming the structures 26A, 26B, 26C and 26D of the biometrics sensing chip 21 are similar to the methods of forming the structures 27A, 27B and 27C of the signal processing chip 23. The biometrics sensing chip 21 and the signal processing chip 23 are disposed on the same horizontal level of the stopper layer 70, as shown in FIG. 7A. In another example, the biometrics sensing chip 21 and the signal processing chip 23 are disposed on different horizontal levels of the stopper layer 70, and this is suitable for the example, in which the biometrics sensing chip 21 and the signal processing chip 23 have different thicknesses (heights), and the biometrics sensing chip 21 and the signal processing chip 23 are electrically connected together, and the signal processing chip 23 and the signal transmission structure 30 are electrically connected together by way of electroplating, grinding, or the like. That is, the structures 27B and 26B may have different heights, and the structures 27C and 26C may also have different heights. In addition, the biometrics sensing chip 21 and the signal processing chip 23 are fixed together through the molding layer 40, thereby easily finishing the structure of one product.

The manufacturing method of the biometrics sensor 100 of the fifth embodiment is similar to that of each of the first and fourth embodiments. Please refer to the structure of FIG. 7A and FIG. 3A to FIG. 4O. First, a biometrics sensing chip 21 and a signal processing chip 23 are provided. Then, one portion of a signal extending structure 26 is formed on the biometrics sensing chip 21 and the signal processing chip 23 to constitute one portion of the biometrics sensing module 20. Next, a base structure 10P, having a base 10 and a signal transmission structure 30 disposed on the base 10, is provided. Then, the portion of the biometrics sensing module 20 is disposed on an upper surface 10A of the base 10 with the signal transmission structure 30 being disposed on one side or sides of the biometrics sensing module 20. Next, a molding layer 40 is utilized and connected to the base 10, the portion of the biometrics sensing module 20 and signal transmission structure 30 with the portion of the signal extending structure 26 being exposed from the molding layer 40. Then, the other portion of the signal extending structure 26 is formed to electrically connect the portion of the signal extending structure 26 to the signal transmission structure 30, and to electrically connect the biometrics sensing chip 21 to the signal processing chip 23. The signal extending structure 26 functionally links with the biometrics sensing chip 21 and the signal processing chip 23 to sense fine biometrics characteristics of an organism F, contacting or approaching the signal extending structure 26, to obtain the biometrics signal transmitted to the signal transmission structure 30. Thus, the sensing surface and the electrical signal interface of the biometrics sensor are substantially disposed on the front side and the back side of the biometrics sensor. The signal processing chip 23 receives and processes a sensing signal, coming from the biometrics sensing chip 21, to obtain the biometrics signal. The other portion of the signal extending structure 26 comprises the outwardly expanded connection structure 26F and the middle connection portion 26M.

With the fingerprint sensor according to each embodiment of the invention, the signal extending structure is used to guide the electrical signal from the front side of the fingerprint sensing chip to the outside of the fingerprint sensing chip, and then the signal transmission structure is utilized to guide the electrical signal to the back side of the sensing chip so that an all-flat fingerprint sensor can be implemented. Because the fingerprint sensor according to each embodiment of the invention can be manufactured using the semiconductor manufacturing process and/or the semiconductor package process, the mass production and the cost down objects can be achieved. Furthermore, disposing the biometrics sensing chip and the signal processing chip separately may also effectively decrease the cost.

While the present invention has been described by way of examples and in terms of preferred embodiments, it is to be understood that the present invention is not limited thereto. To the contrary, it is intended to cover various modifications. Therefore, the scope of the appended claims should be accorded the broadest interpretation so as to encompass all such modifications.

What is claimed is:

1. A biometrics sensor, comprising:
a base;
a biometrics sensing module, which is disposed on an upper surface of the base, and comprises a biometrics sensing chip and a signal extending structure, wherein the signal extending structure is disposed on and electrically connected to the biometrics sensing chip, the signal extending structure and the biometrics sensing chip functionally link with each other to sense a fine biometrics characteristic of an organism, contacting or approaching the biometrics sensor, to obtain a biometrics signal;
a signal transmission structure, which is disposed on the base and one side or sides of the biometrics sensing module, and has a first connection end electrically connected to the signal extending structure, and a second connection end near the base, so that the biometrics signal is transmitted from the biometrics sensing module to the second connection end, wherein the signal extending structure comprises a horizontally outwardly expanded connection structure electrically connecting connection pads of the biometrics sensing chip to the signal transmission structure; and
a molding layer, connected to the base, the biometrics sensing module and the signal transmission structure, so that a sensing surface and an electrical signal interface of the biometrics sensor are disposed on a front side and a back side of the biometrics sensor, respectively.

2. The biometrics sensor according to claim 1, further comprising:
a signal output structure, electrically connected to the second connection end and disposed on the base.

3. The biometrics sensor according to claim 2, wherein the signal transmission structure comprises a conductor layer and a redistribution layer, and the conductor layer is electrically connected to the signal output structure through traces of the redistribution layer.

4. The biometrics sensor according to claim 1, further comprising:
an external protection layer covering the signal extending structure and the molding layer.

5. The biometrics sensor according to claim 1, wherein the biometrics sensing module is disposed on the base through a stopper layer.

6. The biometrics sensor according to claim 1, wherein the biometrics sensing chip further comprises:
a substrate, on which the connection pads is formed; and
a chip protection layer, which is formed on the substrate, partially covers the connection pads, and has windows through which the connection pads are partially exposed from the chip protection layer.

7. The biometrics sensor according to claim 6, wherein the signal extending structure further comprises:
a second molding layer; and
first outward extending electrodes, which are embedded into the second molding layer and disposed on the connection pads, respectively.

8. The biometrics sensor according to claim 1, wherein:
the biometrics sensing chip further comprises: a substrate, on which the connection pads are formed; sensing electrodes formed on the substrate;
and a chip protection layer, which is formed on the substrate, partially covers the sensing electrodes and the connection pads, and has windows through which the connection pads and the sensing electrodes are partially exposed from the chip protection layer; and
the signal extending structure further comprises: a second molding layer; and first outward extending electrodes, which are embedded into the second molding layer and second outward extending electrodes, and are disposed on the connection pads, respectively, wherein the second outward extending electrodes are disposed on the sensing electrodes, respectively.

9. A method of manufacturing a biometrics sensor, the method comprising the steps of:
(a) providing a biometrics sensing chip;
(b) forming one portion of a signal extending structure on the biometrics sensing chip to constitute one portion of a biometrics sensing module;
(c) providing a base structure having a base and a signal transmission structure disposed on the base;
(d) disposing the one portion of the biometrics sensing module on an upper surface of the base with the signal transmission structure being disposed on one side or sides of the biometrics sensing module;
(e) utilizing a molding layer connected to the base, the one portion of the biometrics sensing module and the signal transmission structure with the one portion of the signal extending structure being exposed from the molding layer; and
(f) forming the other portion of the signal extending structure to electrically connect the one portion of the signal extending structure to the signal transmission structure, wherein the signal extending structure comprises a horizontally outwardly expanded connection structure, which electrically connects connection pads of the biometrics sensing chip to the signal transmission structure, the signal extending structure and the biometrics sensing chip functionally link with each other to sense a fine biometrics characteristic of an organism, contacting or approaching the signal extending structure, to obtain a biometrics signal transmitted to the signal transmission structure, so that a sensing surface and an electrical signal interface of the biometrics sensor are disposed on a front side and a back side of the biometrics sensor, respectively.

10. The method according to claim 9, wherein the signal transmission structure has a first connection end electrically connected to the signal extending structure, and a second connection end near the base, and the method further comprises the step of:
(g) forming a signal output structure, electrically connected to the second connection end, on the base.

11. The method according to claim 9, wherein the biometrics sensing chip comprises:
a substrate, on which the connection pads are formed; and a chip protection layer, which is formed on the substrate, partially covers the connection pads and has windows through which the connection pads are partially exposed from the chip protection layer, and the step (b) comprises the following steps:
(b1) forming a seed layer on the chip protection layer and the connection pads;
(b2) forming a patterned resist layer on the seed layer to partially expose the seed layer;
(b3) performing electroplating using the partially exposed seed layer;
(b4) removing the patterned resist layer and a portion of the seed layer to form first outward extending electrodes; and
(b5) pouring a molding compound to form a second molding layer for embedding the first outward extending electrodes of the second molding layer.

12. The method according to claim 9, wherein the biometrics sensing chip comprises: a substrate; connection pads formed on the substrate; and a chip protection layer, which is formed on the substrate, partially covers the connection pads and has windows, through which the connection pads are partially exposed from the chip protection layer, and the step (b) comprises the following steps:
(b1) forming a seed layer on the chip protection layer and the connection pads;
(b2) forming a patterned resist layer on the seed layer to partially expose the seed layer;
(b3) performing electroplating using the partially exposed seed layer;
(b4) removing the patterned resist layer and a portion of the seed layer to form first outward extending electrodes;
(b5) pouring a molding compound to form a second molding layer and a sacrificial protection layer of the biometrics sensing chip; and
(b6) removing the sacrificial protection layer with the second molding layer being left.

13. The method according to claim 9, wherein the step (c) comprises the following steps:
(c1) disposing the base on a carrier wafer;
(c2) forming a seed layer on the base;
(c3) forming a patterned resist layer on the seed layer to partially expose the seed layer;
(c4) performing electroplating using the partially exposed seed layer; and
(c5) removing the patterned resist layer and a portion of the seed layer to form the signal transmission structure.

14. The method according to claim 13, wherein the signal transmission structure has a first connection end electrically connected to the signal extending structure, and a second connection end exposed from the base, and the method further comprises the steps of:
(g) forming a signal output structure, electrically connected to the second connection end, on the base.

15. The method according to claim 9, wherein the step (c) comprises the following steps:
(c1) forming a redistribution layer on a carrier wafer, and disposing the base on the redistribution layer;
(c2) forming a seed layer, electrically connected to the redistribution layer, on the base;
(c3) forming a patterned resist layer on the seed layer to partially expose the seed layer;
(c4) performing electroplating using the partially exposed seed layer; and
(c5) removing the patterned resist layer and a portion of the seed layer to form the signal transmission structure.

16. The method according to claim 15, wherein the signal transmission structure has a first connection end electrically connected to the signal extending structure, and a second connection end near the base, and the method further comprises the step of:
(g) forming a signal output structure, electrically connected to the redistribution layer, on the base.

17. A biometrics sensor, comprising:
a base;
a biometrics sensing module, which is disposed on an upper surface of the base and comprises a biometrics sensing chip, a signal processing chip and a signal extending structure, wherein the signal extending structure is disposed on and electrically connected to the biometrics sensing chip and the signal processing chip, the signal extending structure functionally links with the biometrics sensing chip and the signal processing chip to sense a fine biometrics characteristic of an organism, contacting or approaching the biometrics sensor, to obtain a biometrics signal, and the signal processing chip receives and processes a sensing signal coming from the biometrics sensing chip to obtain the biometrics signal;
a signal transmission structure, which is disposed on the base and one side or sides of the biometrics sensing module, and has a first connection end electrically connected to the signal extending structure, a second connection end near the base and a middle connection portion electrically connected to the biometrics sensing chip and the signal processing chip, wherein the signal transmission structure transmits the biometrics signal from the biometrics sensing module to the second connection end, wherein the signal extending structure comprises a horizontally outwardly expanded connection structure electrically connecting output connection pads of the signal processing chip to the signal transmission structure; and
a molding layer connected to the base, the biometrics sensing module and the signal transmission structure with a sensing surface and an electrical signal interface of the biometrics sensor being disposed on a front side and a back side of the biometrics sensor, respectively.

18. The biometrics sensor according to claim 17, further comprising:
a signal output structure electrically connected to the second connection end and disposed on the base.

19. The biometrics sensor according to claim 18, wherein the signal transmission structure comprises a conductor layer and a redistribution layer, and the conductor layer is electrically connected to the signal output structure through traces of the redistribution layer.

20. The biometrics sensor according to claim 17, further comprising:
an external protection layer covering the signal extending structure and the molding layer.

21. The biometrics sensor according to claim 17, wherein the biometrics sensing module is disposed on the base through a stopper layer.

22. The biometrics sensor according to claim 17, wherein:
the biometrics sensing chip comprises: a substrate; connection pads, formed on the substrate; and a chip protection layer, which is formed on the substrate, partially covers the connection pads, and has windows, through which the connection pads are partially exposed from the chip protection layer; and
the signal processing chip further comprises: a substrate; the output connection pads and input connection pads formed on the substrate; and a chip protection layer, which is formed on the substrate, partially covers the input connection pads and the output connection pads, and has windows, through which the input connection pads and the output connection pads are partially exposed from the chip protection layer.

23. The biometrics sensor according to claim 22, wherein the signal extending structure further comprises:
a second molding layer and a third molding layer; and
first outward extending electrodes embedded into the second molding layer, and third outward extending electrodes and fourth outward extending electrodes embedded into the third molding layer, wherein the first outward extending electrodes are disposed on the connection pads, respectively, the third outward extending electrodes are disposed on the output connection pads, respectively, and the fourth outward extending electrodes are disposed on the input connection pads, respectively.

24. A method of manufacturing a biometrics sensor, the method comprising the steps of:
(a) providing a biometrics sensing chip and a signal processing chip;
(b) forming one portion of a signal extending structure on the biometrics sensing chip and the signal processing chip to constitute one portion of a biometrics sensing module;
(c) providing a base structure having a base and a signal transmission structure disposed on the base;
(d) disposing the one portion of the biometrics sensing module on an upper surface of the base with the signal transmission structure being disposed on one side or sides of the biometrics sensing module;
(e) utilizing a molding layer connected to the base, the one portion of the biometrics sensing module and the signal transmission structure with the one portion of the signal extending structure being exposed from the molding layer; and
(f) forming the other portion of the signal extending structure to electrically connect the one portion of the signal extending structure to the signal transmission structure, and to electrically connect the biometrics sensing chip to the signal processing chip, wherein the signal extending structure functionally links with the biometrics sensing chip and the signal processing chip to sense a fine biometrics characteristic of an organism, contacting or approaching the signal extending structure, to obtain a biometrics signal transmitted to the signal transmission structure, so that a sensing surface and an electrical signal interface of the biometrics sensor are disposed on a front side and a back side of the biometrics sensor, respectively, wherein the signal processing chip receives and processes a sensing signal coming from the biometrics sensing chip to obtain the biometrics signal.

25. The method according to claim 24, wherein the signal transmission structure has a first connection end electrically connected to the signal extending structure, a second connection end near the base and a middle connection portion electrically connected to the biometrics sensing chip and the signal processing chip, wherein the signal extending structure comprises a horizontally outwardly expanded connection structure electrically connecting connection pads of the biometrics sensing chip to the signal transmission structure, and the method further comprises the step of:
(g) forming a signal output structure, electrically connected to the second connection end, on the base.
